(19) United States
(12) Patent Application Publication
(10) Pub. No.: US 2015/0054021 A1
(43) Pub. Date: Feb. 26, 2015

(54) LIGHT-EMITTING DIODE DEVICE

(71) Applicant: EPISTAR CORPORATION, Hsinchu City (TW)

(72) Inventor: Hui-Chun Yeh, Hsinchu City (TW)

(21) Appl. No.: 14/467,537

(22) Filed: Aug. 25, 2014

(30) Foreign Application Priority Data
Aug. 26, 2013 (TW) 102130529

(51) Int. Cl. H01L 33/38

(52) U.S. Cl. CPC H01L 33/38
USPC 257/99

(57) ABSTRACT

A light-emitting diode device comprising: a substrate; a contact light-emitting diode unit formed on the substrate, wherein the contact light-emitting diode unit having a first area; a plurality of light-emitting diode units formed on the substrate wherein one of the plurality of the light-emitting diode units is adjacent to the contact light-emitting diode unit and has a second area and wherein the first area is larger than the second area; a plurality of conductive connecting structures connected to the plurality of the light-emitting diode units and the contact light-emitting diode unit; and a first electrode pad formed on the contact light-emitting diode unit.

### RELATED APPLICATION

This application claims the priority to and the benefit of TW application Ser. No. 102130529 filed on Aug. 26, 2013; the contents of which is incorporated herein by reference in its entirety.

### BACKGROUND

1. Technical Field

The present application relates to a light-emitting diode device, and in particular to an array type light-emitting diode device with high light extraction efficiency.

2. Description of the Related Art

Different from the conventional lighting, the light emission theory and the structures of light-emitting diode devices (LEDs) have advantages such as low power consumption, long life time, without warming-up time, quick response, small volume, shockproof and high productivity. LEDs have been widely used in applications and are easily to form small or array devices, such as the optical display devices, laser diodes, traffic lights, data storage devices, communication devices, and medical devices.

Referring to FIG. 1A and FIG. 1B, a conventional high voltage light-emitting diode device 1 includes a transparent substrate 10, a plurality of light-emitting diode units 12 extended two dimensionally and formed close to each other on the transparent substrate 10. Each epitaxial stack 120 of the light-emitting diode units 12 includes a first semiconductor layer 121, an active layer 122, and a second semiconductor layer 123. Because the transparent substrate 10 is not conductive, gaps 14 formed by etching between the light-emitting diode epitaxial stacks 120 can insulate the light-emitting diode units 12 from each other. Next, a partial exposed area is exposed by etching partial of the epitaxial stacks 120 of the plurality of the light-emitting diode units 12 to the first semiconductor layer 121. Then, forming a conductive connecting structure 19 including a first electrode 18 and a second electrode 16 on the exposed area of the first semiconductor layer 121 of the light-emitting diode epitaxial stack 120 and the second semiconductor layer 123 of adjacent light-emitting diode epitaxial stack 120 respectively. The first electrode 18 and the second electrode 16 respectively comprise a first electrode extension 180 and a second electrode extension 160 formed on the first semiconductor layer 121 of the light-emitting diode epitaxial stack 120 and the second semiconductor layer 123 of adjacent light-emitting diode epitaxial stack 120 to help current spread evenly into the semiconductor layer. The conductive connecting structure 19 selectively connects the second semiconductor layer 123 and the first semiconductor layer 121 of adjacent light-emitting diode units 12 to form serial circuits or parallel circuits among the light-emitting diode units 12. There can be air or an insulating layer 13 beneath the conductive connecting structures 19 wherein the insulating layer 13 is formed on the partial surface of epitaxial stacks of the light-emitting diode unit 12 and the space between the epitaxial stacks of adjacent light-emitting diode units 12 by CVD, PVD, sputtering and so on before forming the conductive connecting structures 19 to protect the epitaxial stacks and insulate the adjacent light-emitting diode units. The material of the insulating layer 13 includes Al₂O₃, SiO₂, AlN, SiNₓ, TiO₂, Ta₂O₅, or the combination thereof.

However, when the conductive connecting structure 19 electrically connects the light-emitting diode units 12, because the depth of the gap 14 between the light-emitting units 12 is large, it is easy to cause bad connection or broken line when forming conductive connecting structures 19 and the yield of the devices is influenced therefore.

Furthermore, the light-emitting diode device 1 mentioned above can connect to other devices to form a light-emitting apparatus. FIG. 2 is a diagram shown the conventional light-emitting apparatus. As shown in FIG. 2, a light-emitting apparatus 100 includes a sub-mount 110 comprising a circuit 101, and the light-emitting diode device 1 is fixed onto the sub-mount 110; an electrical connection structure 104 electrically connects a first electrode pad 16′ and a second electrode pad 18′ of the light-emitting diode device 1 and the circuit 101 of the sub-mount 110. The sub-mount 110 can be the lead frame or the large mounting substrate which is convenient for the circuit layout of the light-emitting diode device 100 and suitable for heat dissipation. The electrical connection structure 104 can be the bonding wires or other connecting structures.

### SUMMARY

A light-emitting diode device comprising: a substrate; a contact light-emitting diode unit formed on the substrate, wherein the contact light-emitting diode unit having a first area; a plurality of light-emitting diode units formed on the substrate wherein one of the plurality of the light-emitting diode units is adjacent to the contact light-emitting diode unit and has a second area and wherein the first area is larger than the second area; a plurality of conductive connecting structures connected to the plurality of the light-emitting diode units and the contact light-emitting diode unit; and a first electrode pad formed on the contact light-emitting diode unit.

### BRIEF DESCRIPTION OF DRAWINGS

The accompanying drawings are included to provide easy understanding of the application, and are incorporated herein and constitute a part of this specification. The drawings illustrate embodiments of the application and, together with the description, serve to illustrate the principles of the application.

FIG. 1A is a structure diagram showing the side view of a conventional array type light-emitting diode device.

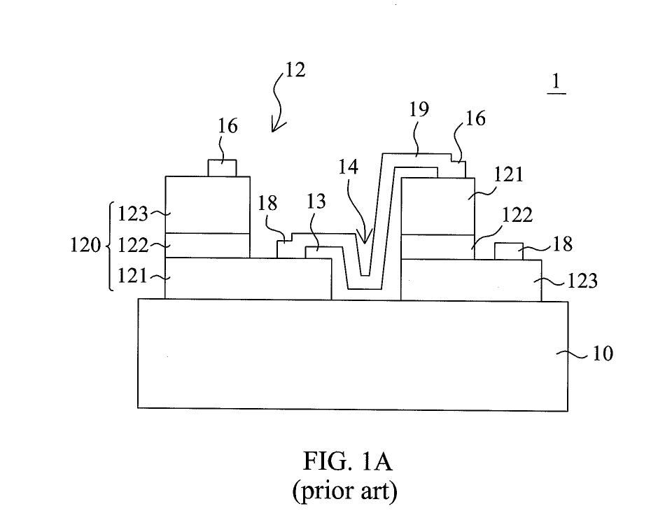

FIG. 1B is a structure diagram showing the top view of a conventional array type light-emitting diode device.

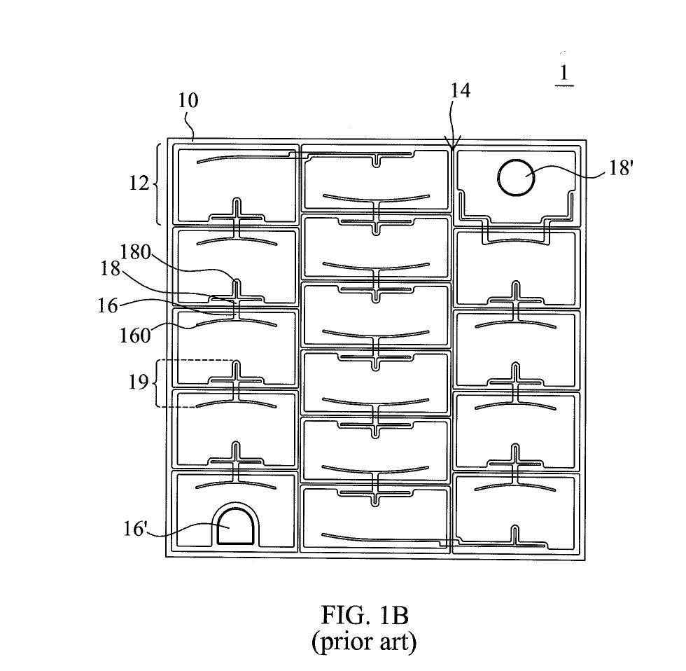

FIG. 2 is a diagram showing the structure of a conventional light-emitting apparatus.

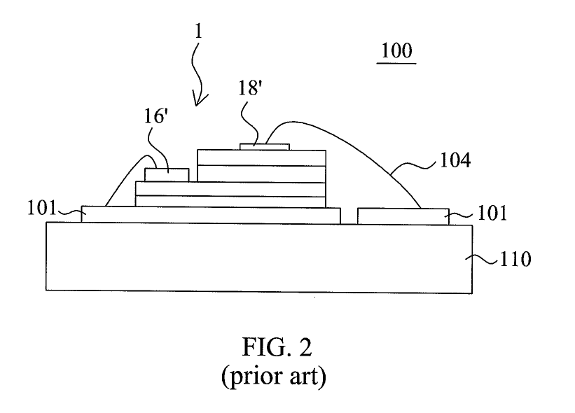

FIG. 3A is a structure diagram showing a sectional view of an array type light-emitting diode device in accordance with the embodiment of the present application.

FIG. 3B is a structure diagram showing the top view of an array type light-emitting diode device in accordance with the embodiment of the present application.

FIG. 4 is a diagram showing the top view of partial of the light-emitting diode device in accordance with the embodiment of the present application.

### DETAILED DESCRIPTION OF THE PREFERRED EMBODIMENTS

Reference is made in detail to the preferred embodiments of the present application, examples of which are illustrated in the accompanying drawings. Wherever possible, the same reference numbers are used in the drawings and the description to refer to the same or like parts.

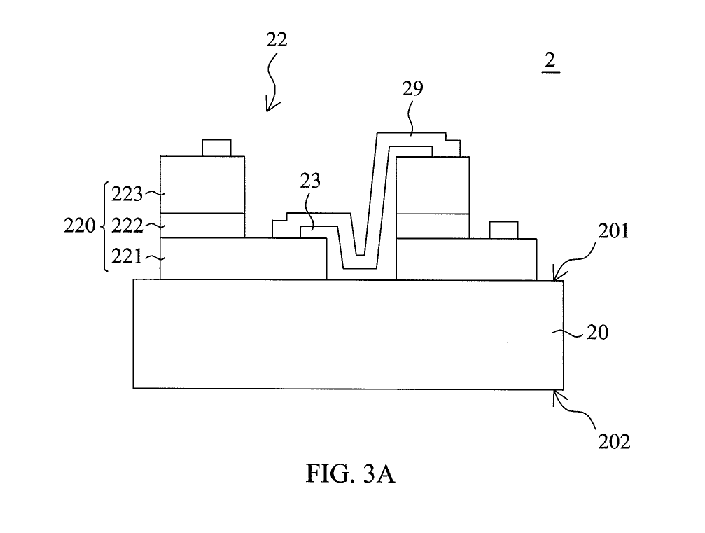

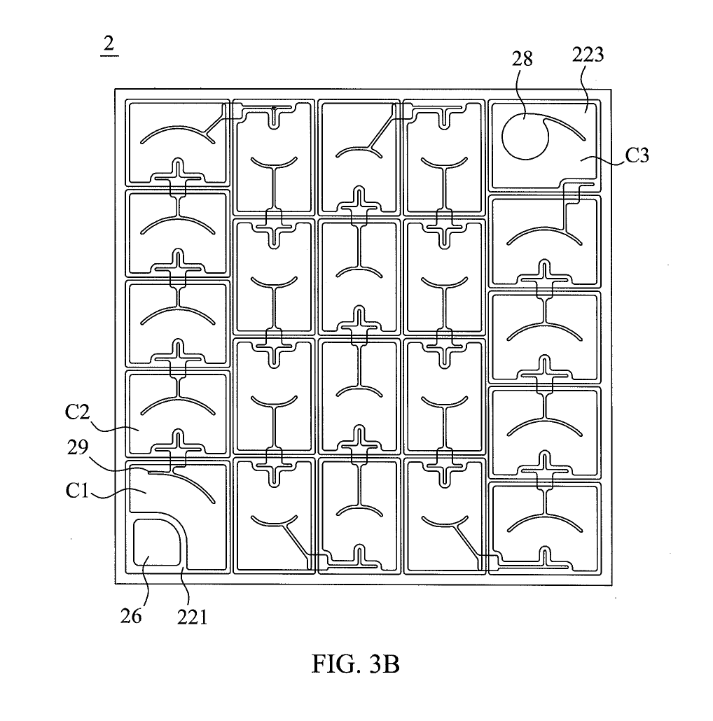

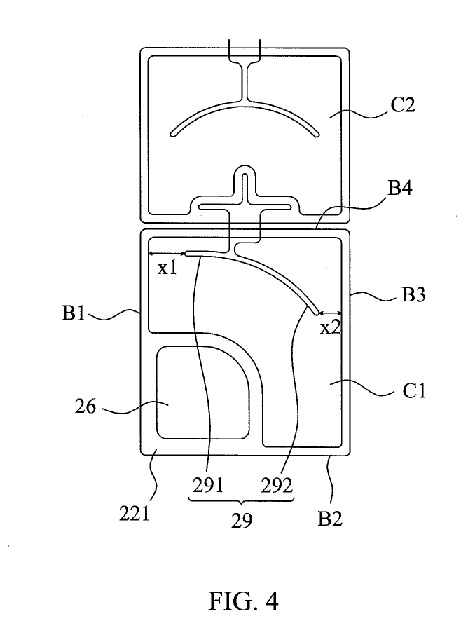

The present disclosure describes an optoelectronic device and a method of fabricating the opto electronic device. In order to have a thorough understanding of the present disclosure, please refer to the following description and the illustrations of FIG. 3A to FIG. 4.

The following shows the description of the embodiments of the present disclosure in accordance with the drawings. As the market demands, the sizes of light-emitting diode devices are miniaturized. When the area of each of the light-emitting diode units of the light-emitting diode device is miniaturized, opaque structures such as electrodes formed on the light extraction surface of the light-emitting diode unit, electrode extensions, and conductive connecting structures affect the light extraction efficiencies of the light-emitting diode units correspondingly.

First, FIG. 3A and FIG. 3B show the sectional view and the top view of an array type light-emitting diode device 2 in accordance with the first embodiment of the present application. The light-emitting diode device 2 has a substrate 20 having a first surface 201 and a bottom surface 202, wherein the first surface 201 is opposite to the bottom surface 202. The substrate 20 can be made of a single material, or can be the composite transparent substrate made of multiple materials. For example, the substrate 20 can be made of a first substrate and a second substrate bonded to each other (not shown). In this embodiment, the material of the substrate 20 is sapphire. However, the material of the substrate 20 can be LiAlO₂ (lithium aluminum oxide), ZnO (zinc oxide), GaP (gallium phosphide), Glass, Organic polymer sheet, AlN (aluminum nitride), GaAs (gallium arsenide), diamond, quartz, Si (silicon), SiC (silicon carbide), and DLC (diamond like carbon). Then, a plurality of two dimensionally extended array type light-emitting diode units 22 is formed on the first surface 201 of the substrate 20. The manufacturing process of the array type light-emitting diode units 22 is described below:

First, an epitaxial stack 220 is formed on the growth substrate (not shown) by a conventional epitaxial growth process and includes a first semiconductor layer 221, an active layer 222, and a second semiconductor layer 223. The material of the growth substrate includes but is not limited to GaAs, Ge (germanium), InP (indium phosphide), sapphire, SiC (silicon carbide), silicon, LiAlO₂ (lithium aluminum oxide), ZnO (zinc oxide), GaN (gallium nitride), and AlN (aluminum nitride). The material of the first semiconductor layer 221, the active layer 222, and the second semiconductor layer 223 includes one or more than one element selected from Ga, Al, In, As, P, N, and Si, for example, aluminum gallium indium phosphide (AlGaInP) series material, aluminum gallium indium nitride (AlGaInN) series material and so on or ZnO-based semiconductor.

Then, as shown in FIG. 3B, a part of the epitaxial stacks 220 is selectively removed by photolithography process to form a plurality of separated light-emitting diode epitaxial stacks 220 on the substrate. Furthermore, partial region of the first semiconductor layer 221 of each light-emitting diode unit is exposed by the photolithography process as a platform for forming the following conductive connecting structures.

In order to increase the light extraction efficiency of the device, the light-emitting diode epitaxial stacks 220 can be disposed on the substrate 20 by substrate transferring and substrate bonding technology. The light-emitting diode epitaxial stacks 220 can be bonded to the substrate 20 directly by heating or pressure, or bonded to substrate 20 by a transparent adhesive layer (not shown), wherein the material of the transparent adhesive layer can be transparent plastic composed of organic polymer, such as polyimide, BCB, PFCB, epoxy, acrylic resin, PET, and PC or the combinations, a transparent conductive layer composed of metal oxide, such as ITO, InO, SnO₂, FTO, ATO, CTO, AZO, and GZO or the combination thereof, or insulating layer composed of inorganic material, such as Al₂O₃, SiNₓ, SiO₂, AlN, TiO₂, and Ta₂O₅ (Tantalum Pentoxide) or the combination thereof.

In fact, people with ordinary skill in the art can easily understand that the method of arranging the light-emitting diode epitaxial stacks 220 on the substrate 20 is not limited to the above. Depending on different structural characteristics, the light-emitting diode epitaxial stacks 220 can be formed directly on the substrate 20 by epitaxial growth. Furthermore, according to different transferring times of the substrate 20, the structure which has a second semiconductor layer 223 adjacent to the first surface 201 of the substrate 20, the first semiconductor layer 221 on the second semiconductor layer 223, and the active layer 222 between the first semiconductor layer 221 and the second semiconductor layer 223 can be formed.

Then, an insulating layer 23 is formed on the partial surface of the light-emitting diode epitaxial stacks 220 and the space between the light-emitting diode epitaxial stacks 220 by CVD, PVD, or sputtering. The insulating layer 23 can protect the epitaxial stacks 220 and insulate the adjacent light-emitting diode units 22. The material of the insulating layer 23 can be Al₂O₃, SiO₂, MN, SiNₓ, TiO₂, and Ta₂O₅ or the combination thereof.

Thereafter, respectively forming a plurality of conductive connecting structures 29 spatially separated from each other on the surface of the first semiconductor layer 221 and the surface of the second semiconductor layer 223 of the adjacent light-emitting diode units by sputtering. The conductive connecting structures 29 are spatially separated from each other and extended along one direction (without any electrodes extending toward other directions) on the first semiconductor layer 221, and are directly contacted with the first semiconductor layer 221 such that the conductive connecting structures 29 electrically connected with each other through the first semiconductor layer 221. These spatially separated conductive connecting structures 29 further extend to the second semiconductor layer 223 of the adjacent light-emitting diode unit 22 with the other end electrically connecting to the second semiconductor layer 223 of the light-emitting diode unit 22 so the adjacent two light-emitting diode units are connected in series.

In fact, people with ordinary skill in the art can easily understand that the methods to electrically connect two adjacent light-emitting diodes are not limited to the above. By arranging the two ends of the conductive connecting structures on the same or different polarities of semiconductor layers of different light-emitting diode units, the light-emitting diode units can connect in series or in parallel by the conductive connecting structures.

Referring to FIG. 3B, in a serial circuit formed by a serially connected array type light-emitting diode device 2, a first electrode pad 26 is formed on the first semiconductor layer 221 of a first contact light-emitting diode unit C1 on the end of the serial circuit. In one embodiment, a second electrode pad 28 is formed on the second semiconductor layer 222 of a second contact light-emitting diode unit C3 on the other end of the serial circuit. The first electrode pad 26 and the second electrode pad 28 can be electrically connected with external power source or other circuit devices by wiring or soldering. Furthermore, the first electrode pad 26, the second electrode pad 28, and the conductive connecting structure 29 can be formed in one process, or can be accomplished by multiple processes. The material of the first electrode pad 26 and the second electrode pad 28 can be the same as or different from the material of the conductive connecting structure 29.

In one embodiment, the first contact light-emitting diode unit C1 has a first area, and any of the adjacent light-emitting diode units C2 has a second area, and the first area of the first contact light-emitting diode unit C1 is larger than the second area of any of the adjacent light-emitting diode units C2. In one embodiment, the difference of the first area of the first contact light-emitting diode unit C1 and the second area of any of the adjacent light-emitting diode units C2 is less than 20%. In one embodiment, the difference of the area of any two of the adjacent light-emitting diode units is less than 20%. Furthermore, to achieve a certain level of conductivity, the material of the first electrode pad 26 and the conductive connecting structures 29 can be metal like Au, Ag, Cu, Al, Pt, Ni, Ti, Sn, the alloy or the combination thereof.

In one embodiment, the first contact light-emitting diode unit C1 has a first shape, and any of the adjacent light-emitting diode units C2 has a second shape. The first shape of the first contact light-emitting diode unit C1 is different from the second shape of any of the adjacent light-emitting diode units C2.

According to the experimental results, the distance of lateral current spreading of the metal conductive connecting structure on the surface of the light-emitting diode unit is limited to about 100 microns (μm). Therefore, in order to spread the current in the semiconductor layer evenly, it is necessary to arrange the conductive connecting structures on the semiconductor layers of the light-emitting diode units to meet the requirement. In addition, the shape of the light-emitting diode units can be changed to adjust the efficiency of current spreading between the light-emitting diode units.

FIG. 4 shows the structure of the light-emitting diode units C2 and the first contact light-emitting diode unit C1 of the light-emitting diode device 2 in serial connection. The first contact light-emitting diode unit C1 has four boundaries B1-B4 in sequence and the first electrode pad 26 is adjacent to the first boundary B1 and the second boundary B2. In order to have uniform efficiency of current spreading, a conductive connecting structures 29 is formed on the fourth boundary B4 of the first contact light-emitting diode unit C1 and the conductive connecting structures 29 has a first extension portion 291 and a second extension portion 292 wherein the first extension portion 291 is extended to the first boundary B1 and the second extension portion 292 is extended to the third boundary B3.

FIG. 4 shows the first extension portion 291 and the first boundary B1 have a shortest distance X₁ therebetween, and the second extension portion 292 and the third boundary B3 have a shortest distance X₂ therebetween. In one embodiment, X₁<80 μm or X₂<80 μm. In another embodiment, X₁+X₂<100 μm, X₁+X₂<90 μm, X₁+X₂<80 μm, X₁+X₂<70 μm, or 0.9≦X₁/X₂≦1.2.

In one embodiment, a buffer layer (not shown) can be optionally disposed between the first semiconductor layer 221 and the substrate 20. The buffer layer is between the two material systems to transit the material system of the substrate 20 to the semiconductor system layer. For the structure of the light-emitting diode, the buffer layer is used to reduce the crystal mismatch between two materials. On the other hand, the buffer layer includes a single layer, multiple layers or a composite structures. The material of the buffer layer can be organic material, inorganic material, metal or semiconductor material. The structure of the buffer layer can be a reflector layer, a thermally conductive layer, an electrically conductive layer, an ohmic contact layer, an anti-deformation layer, a stress release layer, a stress adjustment layer, a bonding layer, a wavelength conversion layer, or a mechanical fixing structure.

A contacting layer (not shown) can be optionally formed on the epitaxial stack 220 away from the substrate 20. Specifically, the contacting layer can be optical layer, electrical layer, or the combination thereof. The optical layer can change the radiation or the light from or entering the active layer 222 wherein the optical layer can change the frequency, the wavelength, the intensity, the flux, the efficiency, the color temperature, rendering index, light field, angle of view, etc. The electrical layer can change the value, density, distribution of voltage, resistance, current and capacitance between any two relative sides of the contacting layer. The material of the contacting layer includes oxide such as conductive oxide, transparent oxide and the oxide with the transparency over 50%, metal such as transparent metal and the metal with transparency over 50%, organic material, inorganic material, fluoresce material, ceramic, semiconductor material and doped semiconductor material. In some applications, the material of the contacting layer can be InTiO, CdSnO, SbSnO, InZnO, ZnAlO or ZnSnO. If the material of the contacting layer is transparent metal, the thickness of the contacting layer is in a range of 0.005 μm˜0.6 μm. Because the contacting layer has better lateral current spreading performance, it can help to spread the current evenly into the epitaxial stack 220 by the physical contact of the contacting layer and the epitaxial stack 220. Generally, the bandgap of the contacting layer varies from 0.5 eV to 5 eV according to dopant types and formation processes.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

Although the drawings and the illustrations above are corresponding to the specific embodiments individually, the element, the practicing method, the designing principle, and the technical theory can be referred, exchanged, incorporated, collocated, coordinated except they are conflicted, incompatible, or hard to be put into practice together.

Although the present application has been explained above, it is not the limitation of the range, the sequence in practice, the material in practice, or the method in practice. Any modification or decoration for present application is not detached from the spirit and the range of such.

What is claimed is:

1. A light-emitting diode device comprising:
a substrate;
a contact light-emitting diode unit formed on the substrate, wherein the contact light-emitting diode unit having a first area;
a plurality of light-emitting diode units formed on the substrate wherein one of the plurality of the light-emitting diode units is adjacent to the contact light-emitting diode unit and has a second area and wherein the first area is larger than the second area;
a plurality of conductive connecting structures connected to the plurality of the light-emitting diode units and the contact light-emitting diode unit; and
a first electrode pad formed on the contact light-emitting diode unit.

2. The light-emitting diode device of claim 1, wherein the contact light-emitting diode unit comprising a first semiconductor layer, a second semiconductor layer formed on the first semiconductor layer, and an active layer formed between the second semiconductor layer and the first semiconductor layer, and/or each of the plurality of the light-emitting diode units comprising a first semiconductor layer, a second semiconductor layer formed on the first semiconductor layer, and an active layer formed between the second semiconductor layer and the first semiconductor layer.

3. The light-emitting diode device of claim 1, wherein each of the plurality of the light-emitting diode units having an area and the difference of the area of any two of the adjacent light-emitting diode units is less than 20%

4. The light-emitting diode device of claim 1, wherein the difference of the first area of the contact light-emitting diode unit and the second area of the adjacent light-emitting diode unit is less than 20%.

5. The light-emitting diode device of claim 1, wherein any two of the conductive connecting structures spatially separated from each other.

6. The light-emitting diode device of claim 2, wherein the first end of one of the plurality of the conductive connecting structures is arranged on the second semiconductor layer of the contact light-emitting diode unit, directly contacted with the second semiconductor layer, and electrically connected with the second semiconductor layer, and the second end of one of the plurality of the conductive connecting structures is arranged on another light-emitting diode unit, and directly contacted with the another light-emitting diode unit.

7. The light-emitting diode device of claim 6, wherein the second end of one of the plurality of the conductive connecting structures is directly contacted with the first semiconductor layer of the another light-emitting diode unit.

8. The light-emitting diode device of claim 2, wherein the first end of one of the plurality of the conductive connecting structures is arranged on the second semiconductor layer of one of the plurality of the light-emitting diode unit, directly contacted with the second semiconductor layer, and electrically connected with the second semiconductor layer, and the second end of one of the plurality of the conductive connecting structures is arranged on another light-emitting diode unit, and directly contacted with the another light-emitting diode unit.

9. The light-emitting diode device of claim 6, wherein the contact light-emitting diode unit has four boundaries, the first electrode pad is adjacent to the first boundary and the second boundary, and the conductive connecting structures has a first extension portion and a second extension portion wherein the first extension portion is extended to the first boundary and the second extension portion is extended to the third boundary.

10. The light-emitting diode device of claim 9, wherein the first extension portion and the first boundary have a shortest distance X₁ therebetween, the second extension portion and the third boundary have a shortest distance X₂ therebetween, and wherein X₁+X₂<100 μm.

11. The light-emitting diode device of claim 9, wherein the first extension portion and the first boundary have a shortest distance X₁ therebetween, the second extension portion and the third boundary have a shortest distance X₂ therebetween, and wherein 0.9≦X₁/X₂≦1.2.

12. The light-emitting diode device of claim 9, wherein the first extension portion and the first boundary have a shortest distance X₁ therebetween, the second extension portion and the third boundary have a shortest distance X₂ therebetween, and wherein X₁<80 μm or X₂<80 μm.
